(19) United States
(12) Patent Application Publication
(10) Pub. No.: US 2025/0210593 A1
(43) Pub. Date: Jun. 26, 2025

(54) STACKED PACKAGE DEVICE WITH INTERCONNECTED SUBSTRATES

(71) Applicant: POWERTECH TECHNOLOGY INC., Hsinchu County (TW)

(72) Inventors: HUNG HSIN HSU, Hsinchu County (TW); LIEN CHIA CHANG, Hsinchu County (TW)

(73) Assignee: POWERTECH TECHNOLOGY INC., Hsinchu County (TW)

(21) Appl. No.: 18/937,564

(22) Filed: Nov. 5, 2024

(30) Foreign Application Priority Data
Dec. 20, 2023 (TW) 112149746

(51) Int. Cl. H01L 25/065; H01L 23/00; H01L 23/13; H01L 23/498; H01L 23/538

(52) U.S. Cl. CPC H01L 25/0657; H01L 23/13; H01L 23/49816; H01L 23/49894; H01L 23/5385; H01L 24/16; H01L 24/32; H01L 24/73; H01L 2224/16227; H01L 2224/26175; H01L 2224/32225; H01L 2224/73204; H01L 2225/06558; H01L 2225/06572

(57) ABSTRACT

A stacked package has a first package and a second package vertically stacked and electrically connected to each other. Any one or each of the first package and the second package includes a first substrate and a second substrate, wherein a chip cavity is formed on an inner surface of the first substrate and a first flip-chip is mounted in the chip cavity. A second flip-chip facing the chip cavity is mounted on an inner surface of the second substrate. Multiple inner pads are respectively formed on opposite surfaces of the first and the second substrates for interconnecting the substrates electrically. Because no encapsulant is provided to cover the first flip-chip and the second flip-chip, the problem of separation between the encapsulant and the substrates is avoided.

### CROSS REFERENCE TO RELATED APPLICATIONS

This non-provisional application claims the benefit under 35 U.S.C. § 119(a) to Patent Application No. 112149746 filed in Taiwan on Dec. 20, 2023, which is hereby expressly incorporated by reference into the present application.

### BACKGROUND OF THE INVENTION

### 1. Field of the Invention

The present invention relates to a stacked package device, particularly to a stacked package device including opposite substrates interconnected to each other.

### 2. Description of the Related Art

In order to integrate different types of or multiple package elements, package on package (PoP) technology is proposed to stack packages into a miniaturized component to reduce space occupation as much as possible in electronic products.

With reference to FIG. 5, according to conventional PoP technology, a top package 100 is placed above and electrically connected to a bottom package 200. Both the top package 100 and the bottom package 200 contain a respective chip. For a high bandwidth PoP, the bottom package 200 may have a top substrate 201, a bottom substrate 202 and a plurality of conductive pillars 230 vertically interconnected between the top substrate 201 and the bottom substrate 202. Encapsulant 240 (EMC) is provided to fill space between the top substrate 201 and the bottom substrate 202 and encapsulate the chip inside the bottom package 200.

The conductive pillars 230 provided between the top substrate 201 and the bottom substrate 202 are usually formed by the electroplating process. However, the conductive pillars 230 may have voids formed therein during the electroplating process. When the conductive pillars 230 are subjected to thermal stress, the voids may cause damage to the conductive pillars 230 and deteriorate their electrical transmission capability. Further, because the encapsulant 240 and the two substrates 201, 202 have different coefficients of thermal expansion (CTE), the encapsulant 240 may be separated from any of the two substrates 201, 202 when they are heated.

### SUMMARY OF THE INVENTION

An objective of the present disclosure is to provide a stacked package device without using encapsulant so as to mitigate possible damages to the structure of the stacked package caused by thermal stress.

The stacked package device comprises a first package, a second package, and multiple external connecting members.

The second package is connected to the first package in a stacked arrangement, and the second package comprises:
a first substrate comprising:
   an outer surface and an inner surface opposite to each other, with the outer surface electrically connected to the first package;
   a chip cavity extending inward from the inner surface in a direction toward the outer surface, and having an inner bottom surface and an inner sidewall;
   first flip-chip electrically mounted on the inner bottom surface of the chip cavity; and
   a protection layer covering the inner bottom surface and the inner sidewall of the chip cavity;
a second substrate comprising:
   an outer surface and an inner surface opposite to each other, with the inner surface of the second substrate electrically connected to the inner surface of the first substrate; and
   a second flip-chip electrically mounted on the inner surface of the second substrate and at a position corresponding to the chip cavity.

The multiple external connecting members are provided on the outer surface of the second substrate.

Based on the above, the first substrate and the second substrate can be electrically interconnected to each other in the package. The chip cavity formed in the substrate can accommodate the first flip-chip and second flip-chip without needing encapsulant to cover the chips. The problem of separation between the encapsulant and the substrates resulting from inconsistent coefficients of thermal expansion (CTE) can be avoided. Furthermore, since there is no copper pillar manufactured in the encapsulant, damage to the copper pillar caused by thermal stress can be eliminated.

Other objectives, advantages and novel features of the invention will become more apparent from the following detailed description when taken in conjunction with the accompanying drawings.

### BRIEF DESCRIPTION OF THE DRAWINGS

FIG. 1 is a cross section view of a stacked package device according to an embodiment of the invention;

FIG. 2 is a cross section view of a stacked package device according to another embodiment of the invention;

FIG. 3 is a cross section view of a stacked package device according to yet another embodiment of the invention;

FIG. 4 is a cross section view of a stacked package device according to yet another embodiment of the invention; and

FIG. 5 is a cross section view of a conventional stacked package device.

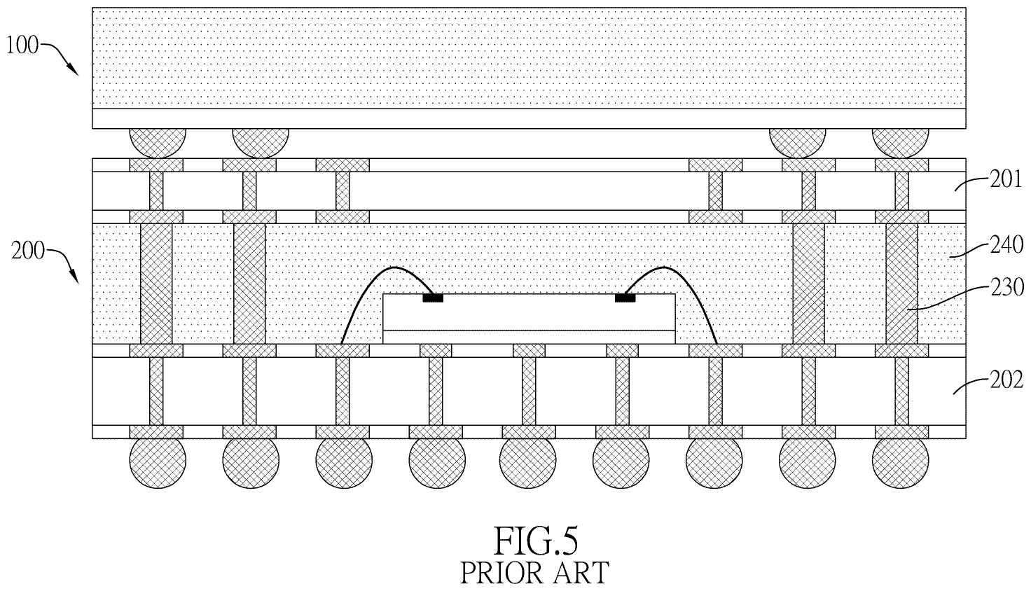

### DETAILED DESCRIPTION OF THE INVENTION

Directional terms as used herein, for example, up, down, right, left, front, back, top, bottom are made only with reference to the figures as illustrated and are not intended to imply absolute orientation unless otherwise specified.

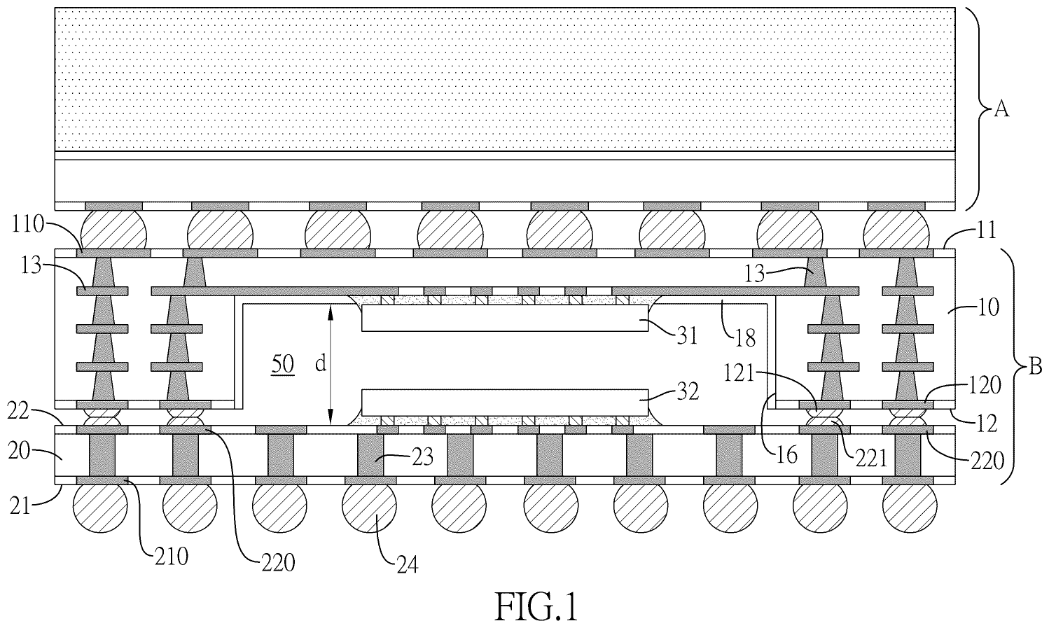

With reference to FIG. 1, according to one embodiment of the invention, a stacked package device comprises a first package A and a second package B. The first package A is vertically mounted above the second package B. Any one or both of the first package A and the second package B may have configuration as described below. In the embodiment, the first package A may be a package of any type and include non-specific components therein. As an example, the first package A may contain a memory chip therein. The second package B comprise a first substrate 10, a second substrate 20, a first flip-chip 31 and a second flip-chip 32 as shown in the drawings.

The first substrate 10 has an outer surface 11 and an inner surface 12 opposite to each other. Multiple outer pads 110 are provided on the outer surface 11 that faces the first package A for electrically connecting to the first package A. In an example, the outer pads 110 are electrically connected to the first package A through respective solder balls.

A chip cavity 16 is formed in the inner surface 12 of the first substrate 10 and extends inward from the inner surface 12 in a direction toward the outer surface 11. On an inner bottom surface of the chip cavity 16, a first flip-chip 31 is electrically mounted. The first flip-chip 31 may have a plurality of contacts formed on its bottom to be electrically connected to the inner surface 12. Underfill may fill space between the bottom of the first flip-chip 31 and the first substrate 10. Multiple inner pads 120, which are formed on the inner surface 12 and around the chip cavity 16, electrically connect to the respective outer pads 110 through a first redistribution layer 13 in the first substrate 10. In one embodiment, a pitch between the inner pads 120 is smaller than a pitch between the outer pads 110.

In this embodiment, a protection layer 18 is further applied to cover the inner bottom surface and an inner sidewall of the chip cavity 16. The protection layer 18 is configured to protect metal layer exposed in the chip cavity 16. For example, the protection layer 18 may cover and protect portions of the first redistribution layer 13 being exposed in the chip cavity 16.

The second substrate 20 has an outer surface 21 and an inner surface 22 opposite to each other, where the inner surface 22 faces and is spaced from the inner surface 12 of the first substrate 10 by a distance d. The second flip-chip 32 is mounted on the inner surface 22 of the second substrate 20 by a plurality of contacts that are formed on a bottom of the second flip-chip 32 and electrically connected to the inner surface 22. Non-active surfaces of both the first flip-chip 31 and the second flip-chip 32 face to each other, but are separated by a gap. Underfill may be used to fill space between the second flip-chip and the second substrate 20. When filling the underfill under the first flip-chip 31 or the second flip-chip 32, voids may occur in the underfill during the curing process. If there is moisture inside the underfill, these voids allow the moisture to escape from inside, preventing the moisture from trapping in the space between the chip and the substrate.

The second substrate 20 further has multiple inner pads 220 formed on the inner surface 22 and around the second flip-chip 32 for electrically connecting to the inner pads 120 of the first substrate 10. According to an embodiment, conductive bumps 121, 221 are formed on pad surfaces of the inner pads 120, 220 and connected to each other respectively.

Multiple outer pads 210 are formed on the outer surface 21 and electrically connected to the respective inner pads 220 through a second redistribution layer 23 in the second substrate 20. In one embodiment, a pitch between the inner pads 220 is smaller than a pitch between the outer pads 210.

Further, multiple external connecting members 24 such as solder balls are configured respectively on the outer pads 210 as connecting pads of the stacked package device for electrically connecting to another device.

A chip accommodating chamber 50 is formed between the chip cavity 16 and the second substrate 20 for placing the first flip-chip 31 and the second flip-chip 32 therein. Non-active surfaces and lateral surfaces of the first flip-chip 31 and the second flip-chip 32 are uncovered by any encapsulant (EMC), but exposed in the chip accommodating chamber 50. A relative distance between the first flip-chip 31 and the second flip-chip 32 may be determined by a depth of the chip cavity 16, wherein the depth of the chip cavity 16 may be greater than the sum of the heights of the first flip-chip 31 and the second flip-chip 32.

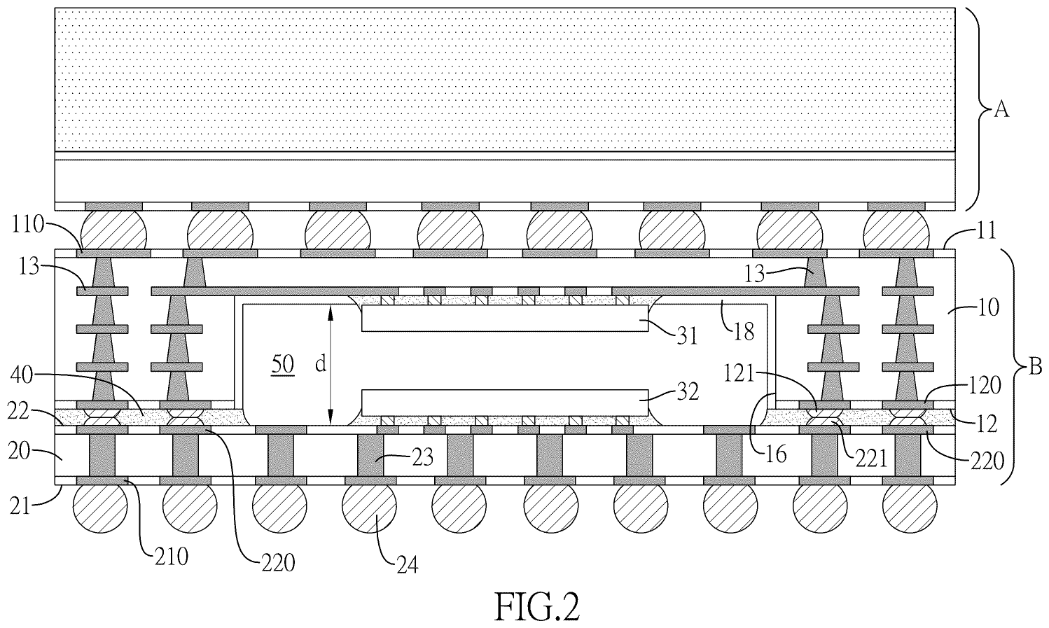

With reference to FIG. 2, according to another embodiment of the invention, after the conductive bumps 121, 221 are respectively connected to each other, an underfill 41 is provided to fill space between the opposite inner surfaces 12, 22 and cover each conductive bump 121, 221 to protect them from breakage or disconnection resulting from stress.

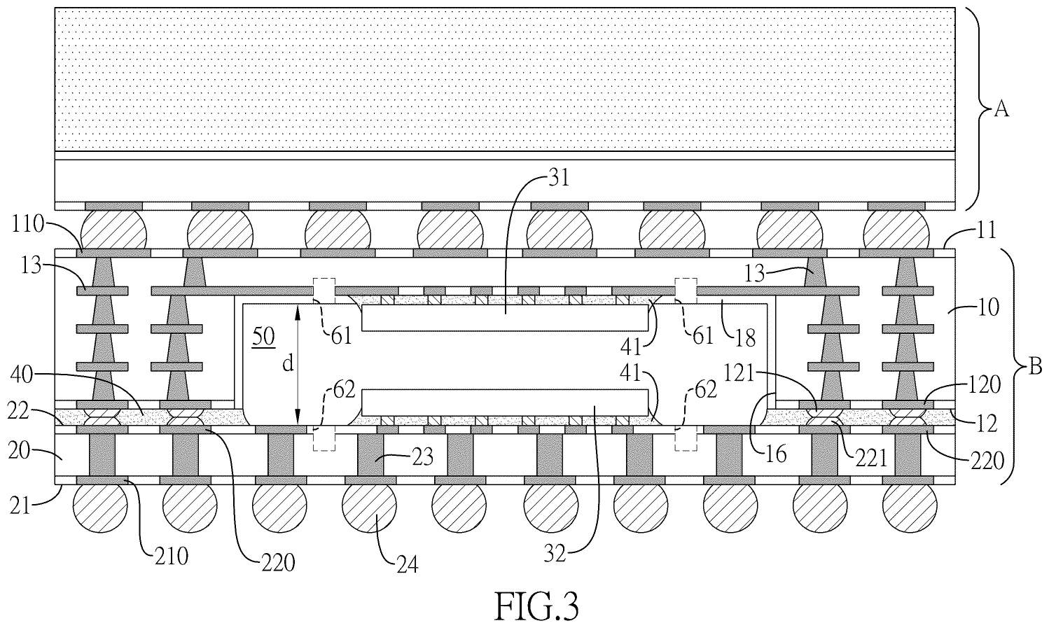

With reference to FIG. 3, according to another embodiment, a first annular groove 61 is formed in the inner bottom surface of the chip cavity 16 and around the first flip-chip 31, and a second annular groove 62 is formed in the inner surface 22 of the second substrate 20 and around the second flip-chip 32. Both the first annular groove 61 and the second annular grove 62 for anti-overflow purpose are formed within the chip accommodating chamber 50. When injecting an underfill 40,41, the first annular groove 61 and the second annular grove 62 prevent excessive underfill 40,41 from spreading outward. In one embodiment, the first annular groove 61 corresponds to the second annular groove 62 in position. In another embodiment, the first annular groove 61 and the second annular groove 62 are arranged in a staggered arrangement.

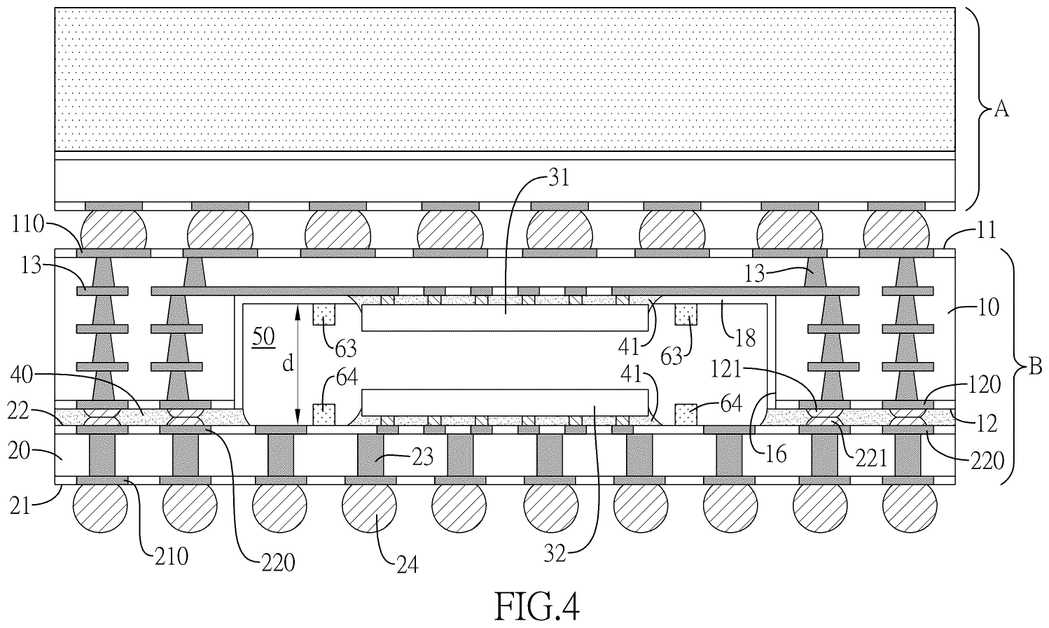

With reference to FIG. 4, according to yet another embodiment, a first annular dam 63 is formed on the inner bottom surface of the chip cavity 16 and around the first flip-chip 31. A second annular dam 64 is formed on the inner surface 22 of the second substrate 20 and around the second flip-chip 32. Both the first annular dam 63 and the second annular dam 64 are within the chip accommodating chamber 50. When injecting the underfill 40,41, the first annular dam 63 and the second annular dam 64 block excessive underfill 40,41. In one embodiment, the first annular dam 63 and the second annular dam 64 are arranged in a staggered arrangement. In another embodiment, the first annular dam 63 is greater in height than the first flip-chip 31, and the second annular dam 64 is greater in height than the second flip-chip 32.

According to the invention, the first substrate and the second substrate can be electrically interconnected to each other through pads, and flip-chip may be placed in the chip cavity formed in one substrate without being covered by encapsulant so that the problem of separation between the encapsulant and the substrates resulting from their inconsistent coefficients of thermal expansion can be avoided. Furthermore, since there are no copper pillars manufactured in the encapsulant, damage to the copper pillars caused by thermal stress is prevented.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A stacked package device comprising:
a first package;
a second package connected to the first package in a stacked arrangement, the second package comprising:
a first substrate comprising:
an outer surface and an inner surface opposite to each other, with the outer surface electrically connected to the first package;
a chip cavity extending inward from the inner surface in a direction toward the outer surface;
a first flip-chip electrically mounted on an inner bottom surface of the chip cavity; and
a protection layer covering the inner bottom surface and an inner sidewall of the chip cavity;
a second substrate comprising:
an outer surface and an inner surface opposite to each other, with the inner surface of the second substrate electrically connected to the inner surface of the first substrate; and
a second flip-chip electrically mounted on the inner surface of the second substrate and corresponding to the chip cavity in position; and
multiple external connecting members provided on the outer surface of the second substrate.

2. The stacked package device as claimed in claim 1 comprising:
a first annular groove formed in the inner bottom surface of the chip cavity in the first substrate and around the first flip-chip; and
a second annular groove formed in the inner surface of the second substrate and around the second flip-chip.

3. The stacked package device as claimed in claim 2, wherein the first annular groove corresponds to the second annular groove in position.

4. The stacked package device as claimed in claim 2, wherein the first annular groove and the second annular groove are arranged in a staggered arrangement.

5. The stacked package device as claimed in claim 1 comprising:
a first annular dam formed on the inner bottom surface of the chip cavity of the first substrate and around the first flip-chip; and
a second annular dam formed on the inner surface of the second substrate and around the second flip-chip.

6. The stacked package device as claimed in claim 5, wherein the first annular dam and the second annular dam are arranged in a staggered arrangement.

7. The stacked package device as claimed in claim 5, wherein
the first annular dam is greater in height than the first flip-chip; and
the second annular dam is greater in height than the second flip-chip.

8. The stacked package device as claimed in claim 1, wherein non-active surfaces and lateral surfaces of both the first flip-chip and the second flip-chip are exposed in the chip cavity.

9. The stacked package device as claimed in claim 1, wherein
the first substrate further comprises:
multiple inner pads formed on the inner surface;
multiple outer pads formed on the outer surface and electrically connected to the inner pads respectively through a first redistribution layer in the first substrate;
wherein a pitch between the inner pads is smaller than a pitch between the outer pads; and
the second substrate further comprises:
multiple inner pads formed on the inner surface of the second substrate;
multiple outer pads formed on the outer surface of the second substrate and electrically connected to the inner pads of the second substrate respectively through a second redistribution layer in the first substrate; and
wherein a pitch between the inner pads of the second substrate is smaller than a pitch between the outer pads of the second substrate.

10. The stacked package device as claimed in claim 1, wherein the chip cavity has a depth greater than a sum of heights of the first flip-chip and the second flip-chip.
